(19) United States
(12) Patent Application Publication
(10) Pub. No.: US 2014/0253095 A1
(43) Pub. Date: Sep. 11, 2014

(54) PHASE DETECTING SYSTEM FOR THREE PHASE ALTERNATING CURRENT

(71) Applicants: HON HAI PRECISION INDUSTRY CO., LTD., New Taipei (TW); HONG FU JIN PRECISION INDUSTRY (WuHan) CO., LTD., Wuhan (CN)

(72) Inventors: PENG ZHANG, Wuhan (CN); YU-LIN LIU, Wuhan (CN)

(73) Assignees: HON HAI PRECISION INDUSTRY CO., LTD., New Taipei (TW); HONG FU JIN PRECISION INDUSTRY (WuHan) CO., LTD., Wuhan (CN)

(21) Appl. No.: 14/065,642

(22) Filed: Oct. 29, 2013

(30) Foreign Application Priority Data
Mar. 7, 2013 (CN) 201310071596X

(51) Int. Cl. G01R 25/00

(52) U.S. Cl. CPC G01R 25/00
USPC 324/76.82

(57) ABSTRACT

An alternating current phase detecting system includes a first arithmetic circuit, a second arithmetic circuit, and an inverted output module connected to the second arithmetic circuit. The first arithmetic circuit receives any first alternating current signal and the second arithmetic circuit receives a second alternating current signal. The first alternating current signal is converted to a first output signal and is output to the second arithmetic circuit. The second arithmetic circuit outputs a second output signal to the inverted output module which is fed by the second alternating current signal and the first output signal. The inverted output module obtains a phase value difference between the first alternating current signal and the second alternating current signal to establish 120 degree sequentiality between the two, or otherwise, to enable correct electrical connections to be made to a powered device.

### BACKGROUND

1. Technical Field

The present disclosure generally relates to a systems for detecting the phase of a three phase alternating current.

2. Description of Related Art

Three phase alternating current system includes three output terminals for outputting three alternating currents in different phases. The three alternating currents have the same frequency and there is 120 degrees between two adjacent alternating currents. However, three alternating currents can burn out the device being powered when the three terminals of three phase alternating current system are wrongly connected to the device.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is a schematic view of one embodiment of a phase detecting system.

FIG. 2 is a circuit diagram of one embodiment of a phase detecting system.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

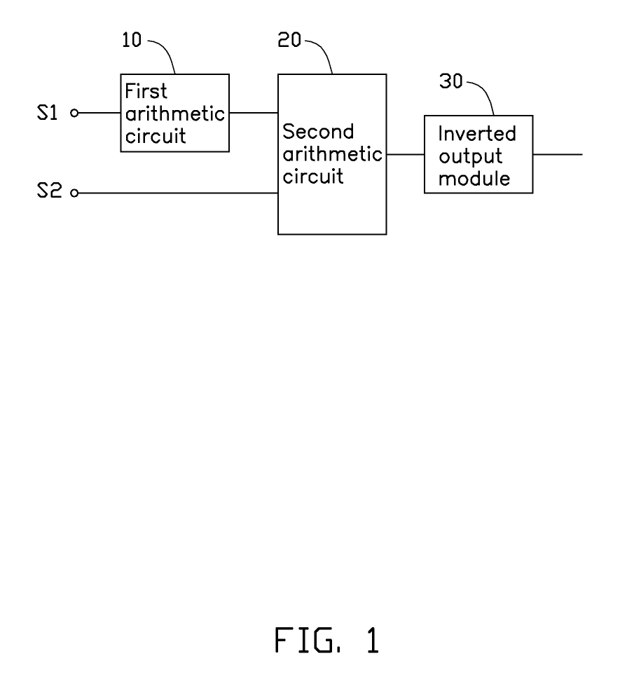

FIG. 1 shows a phase detecting system according to one embodiment. The phase detecting system includes a first arithmetic circuit 10 and a second arithmetic circuit 20 connected to the first arithmetic circuit 10. The first arithmetic circuit 10 is connected to a first alternating current output terminal 51 of a three phase alternating current system and the second arithmetic circuit 20 is connected to a second alternating current output terminal S2 of the three phase alternating current system. The phase detecting system further includes an inverted output module 30 connected to the second arithmetic circuit 20.

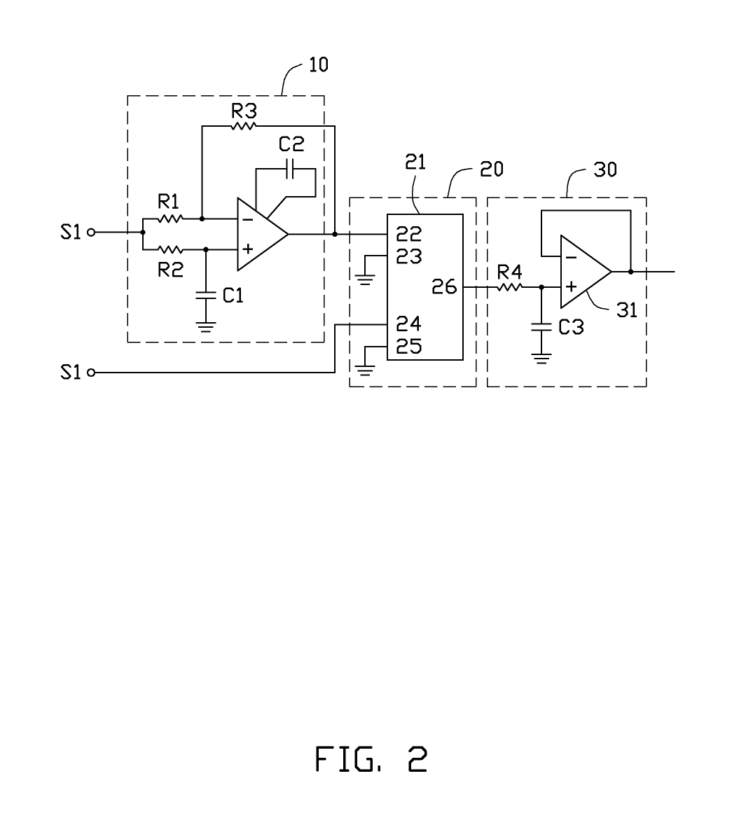

Referring to FIG. 2, the first arithmetic circuit 10 includes a resistor R1, a resistor R2, a resistor R3, a capacitor C1, a capacitor C2, and an operational amplifier 11. The first alternating current output terminal S1 is connected to a reverse input end of the operational amplifier 11 via the resistor R1. The first alternating current output terminal S1 is connected to a positive input end of the operational amplifier 11 via the resistor R2. The positive input end is grounded via the capacitor C1. The reverse input end is connected to an output end of the operational amplifier 11 via the resistor R3. In one embodiment, the resistance value of the resistor R1, R2, R3, is 10 KΩ. The value of the capacitor C1 is 0.015 uF. The value of the capacitor C2 is 10 uF. The model of the operational amplifier 11 is AD301A.

The second arithmetic circuit 20 includes a chip 21. The chip 21 includes a first input pin 22, a first ground pin 23, a second input pin 24 and a second ground pin 25. The output end of the operational amplifier 11 is connected to the first input pin 22. The first ground pin 23 is grounded. The second alternating current output terminal S2 is connected to the second input pin 24. The second ground pin 25 is grounded. In one embodiment, the model of the chip 21 is AD532SH.

The inverted output module 30 includes a resistor R4, a capacitor C3, and a phase reverser 31. The output pin of the chip 21 is connected to the positive input terminal of the phase reverser 31. The reverse input terminal of the phase reverser 31 is connected to the output terminal of the phase reverser 31. In one embodiment, the model of the phase reverser 31 is AD 741. The resistance value of the resistor R4 is 100 KΩ. The value of the capacitor C3 is 1 uF.

The first arithmetic circuit 10 receives a first alternating current signal from the first alternating current output terminal S 1. The first alternating current signal is a sinusoidal signal equal to U*sin ωt. The first alternating current signal is converted to a first output signal equal to -U*cos ωt via the first arithmetic circuit 10 and is outputted from the output end of the first arithmetic circuit 10 to the first input pin 22 of the chip 21. The second input pin 24 of the second arithmetic circuit 20 receives a second alternating current signal from the second alternating current output terminal S2. The second alternating current signal is equal to U*sin(ωt−φ). The second arithmetic circuit 20 converts the second alternating current signal to a second output signal and outputs the second output signal to the phase reverser 31. The second output signal is equal to −U*U5*sin φ/20. The phase reverser 31 converts the second output signal to obtain a phase value φ and outputs the phase value φ to a display (not shown) to display. The phase value is the difference between the first alternating current output terminal S1 and the second alternating current output terminal S2. If the phase value is equal to 120 degrees, the first alternating current output terminal S1 and the second alternating current output terminal S2 are determined to be sequential and adjacent output terminals of the three phase alternating current system. Having established two terminals which operate in sequence, the correct connection of the three phase alternating current system to the device to be powered is simple.

It is to be understood, however, that even though numerous characteristics and advantages of the embodiments have been set forth in the foregoing description, together with details of the structure and function of the embodiments, the disclosure is illustrative only, and changes may be made in detail, especially in the matters of shape, size, and arrangement of parts within the principles of the present disclosure to the full extent indicated by the broad general meaning of the terms in which the appended claims are expressed.

What is claimed is:

1. A phase detecting system comprising:
a first arithmetic circuit, the first arithmetic circuit configured to receive a first alternating current signal of a three phase alternating current;
a second arithmetic circuit, the second arithmetic circuit configured to receive a second alternating current signal of the three phase alternating current;
an inverted output module connected to the second arithmetic circuit;
wherein the first arithmetic circuit is configured to convert the first alternating current signal to a first output signal and output the first output signal to the second arithmetic circuit; the second arithmetic circuit is configured to output a second output signal to the inverted output module according to the second alternating current signal and the first output signal; and the inverted output module is configured to obtain a phase value according to the second output signal; and the phase value is a phase difference between the first alternating current signal and the second alternating current signal.

2. The phase detecting system of claim 1, wherein the first arithmetic circuit comprises an operational amplifier; the second arithmetic circuit comprises a chip; the inverted output module comprises a phase reverser; a positive input end of the operational amplifier is connected to a first resistor and is configured to receive the first alternating current signal via the first resistor; a reverse input end of the operational amplifier is connected to a second resistor and is configured to receive the first alternating current signal via the second resistor; an output end of the operational amplifier is connected to a first input pin of the chip; the reverse input end is connected to the output end via a third resistor; a second input pin of the chip is configured to receive the second alternating current signal; an output pin of the chip is connected to a positive input terminal of the phase reverser; a reverse input terminal of the phase reverser is connected to an output terminal of the phase reverser; and the output terminal is configured to output the phase value.

3. The phase detecting system of claim 2, wherein the positive input end is grounded via a capacitor.

4. The phase detecting system of claim 2, wherein the output pin is connected to the positive input terminal via a fourth resistor.

5. The phase detecting system of claim 2, wherein the positive input terminal is grounded via a capacitor.

6. The phase detecting system of claim 2, wherein the model of operational amplifier is AD301A.

7. The phase detecting system of claim 2, wherein the model of the chip is AD532SH.

8. The phase detecting system of claim 2, wherein the model of the phase reverser is AD741.

9. A phase detecting system assembly comprising:
a three phase alternating current system, the three phase alternating current system comprises a first alternating current output terminal and a second alternating current output terminal;
a first arithmetic circuit, the first arithmetic circuit is connected to the first alternating current output terminal;
a second arithmetic circuit, the second arithmetic circuit is connected to the second alternating current output terminal; and
an inverted output module connected to the second arithmetic circuit;
wherein the first arithmetic circuit is configured to convert a first alternating current signal sent from the first alternating current output terminal to a first output signal and output the first output signal to the second arithmetic circuit; the second arithmetic circuit is configured to output a second output signal to the inverted output module according to a second alternating current signal, sent from the second alternating current output terminal, and the first output signal; and the inverted output module is configured to obtain a phase value according to the second output signal; and the phase value is a phase difference between the first alternating current signal and the second alternating current signal.

10. The phase detecting system assembly of claim 9, wherein the first arithmetic circuit comprises an operational amplifier; the second arithmetic circuit comprises a chip; the inverted output module comprises a phase reverser; a positive input end of the operational amplifier is connected to a first resistor and is connected to the first alternating current output terminal via the first resistor; a reverse input end of the operational amplifier is connected to a second resistor and is connected to the first alternating current output terminal via the second resistor; an output end of the operational amplifier is connected to a first input pin of the chip; the reverse input end is connected to the output end via a third resistor; a second input pin of the chip is connected to the second alternating current output terminal; an output pin of the chip is connected to a positive input terminal of the phase reverser; a reverse input terminal of the phase reverser is connected to an output terminal of the phase reverser; and the output terminal is configured to output the phase value.

11. The phase detecting system assembly of claim 10, wherein the positive input end is grounded via a capacitor.

12. The phase detecting system assembly of claim 10, wherein the output pin is connected to the positive input terminal via a fourth resistor.

13. The phase detecting system assembly of claim 10, wherein the positive input terminal is grounded via a capacitor.

14. The phase detecting system assembly of claim 10, wherein the model of operational amplifier is AD301A.

15. The phase detecting system assembly of claim 10, wherein the model of the chip is AD532SH.

16. The phase detecting system assembly of claim 10, wherein the model of the phase reverser is AD741.
